(19) United States
(12) Patent Application Publication
(10) Pub. No.: US 2018/0151837 A1
(43) Pub. Date: May 31, 2018

(54) DISPLAY DEVICE

(71) Applicant: Japan Display Inc., Tokyo (JP)

(72) Inventor: Masamitsu FURUIE, Tokyo (JP)

(21) Appl. No.: 15/814,469

(22) Filed: Nov. 16, 2017

(30) Foreign Application Priority Data
Nov. 29, 2016 (JP) 2016-230950

(51) Int. Cl. H01L 51/52; H01L 27/32; H01L 51/00

(52) U.S. Cl. CPC H01L 51/5253; H01L 27/3251; H01L 51/0097; H01L 27/323

(57) ABSTRACT

A display device includes a first substrate, a second substrate opposed to the first substrate, a display region between the first substrate and the second substrate, a peripheral region outside the display region between the first substrate and the second substrate, an adhesive member adhering the first substrate and the second substrate, an interlayer insulating film between the first substrate and the second substrate, a light emitting element arranged in the display region, a sealing film between the interlayer insulating film and the second substrate, the light emitting element and the interlayer insulating film arranged between the sealing film and the first substrate, and a sealing film protective layer between the sealing film and the second substrate, the adhesive member arranged between the sealing film protective layer and the second substrate.

### CROSS REFERENCE TO RELATED APPLICATIONS

This application is based upon and claims the benefit of priority from the prior Japanese Patent Application No. 2016-230950, filed on Nov. 29, 2016, the entire contents of which are incorporated herein by reference.

### FIELD

An embodiment of the present invention is related to a display device.

### BACKGROUND

Conventionally, an organic EL display device (Organic Electroluminescence Display) using an organic electroluminescence material (organic EL material) as a light emitting element (organic EL element) of a display part is known as a display device. Unlike a liquid crystal display device or the like, an organic EL display device is a so-called self-light emitting type display device which realizes display by causing an organic EL material to emit light.

In recent years, in such an organic EL display device, covering the light emitting element with a sealing film in order to protect it from moisture or the like has been examined. For example, an organic EL display device has been disclosed in which a sealing film is arranged on a display element to protect the display element from moisture or the like (for example, US Patent Application Publication No. 2015/0380675).

### SUMMARY

A display device in an embodiment according to the present invention includes a first substrate, a second substrate opposed to the first substrate, a display region between the first substrate and the second substrate, a peripheral region outside the display region between the first substrate and the second substrate, an adhesive member adhering the first substrate and the second substrate, an interlayer insulating film between the first substrate and the second substrate, a light emitting element arranged in the display region, a sealing film between the interlayer insulating film and the second substrate, the light emitting element and the interlayer insulating film arranged between the sealing film and the first substrate; and a sealing film protective layer between the sealing film and the second substrate, the adhesive member arranged between the sealing film protective layer and the second substrate. The sealing film includes a first inorganic insulating film, an organic insulating film, and a second inorganic insulating film, the sealing film protective layer has a region in contact with an end part of the first inorganic insulating film and an end part of the second inorganic insulating film in the peripheral region, the first inorganic insulating film has a region in contact with the second inorganic insulating film in the peripheral region, and the adhesive member does not overlap an end part of the sealing film protective layer in the peripheral region.

A display device in an embodiment according to the present invention includes a first substrate, a second substrate arranged with a barrier layer on a surface opposing the first substrate, a display region between the first substrate and the second substrate, a peripheral region outside the display region between the first substrate and the second substrate, an adhesive member adheres the first substrate and the second substrate, an interlayer insulating film between the first substrate and the second substrate, a light emitting element arranged in the display region, a sealing film between the interlayer insulating film and the second substrate, the light emitting element and the interlayer insulating film arranged between the sealing film and the first substrate; and a sealing film protective layer between the sealing film and the second substrate, the adhesive member arranged between the sealing film protective layer and the second substrate. The second substrate includes a barrier film opposite the first substrate, the sealing film includes a first inorganic insulating film, an organic insulating film, and a second inorganic insulating film, the first inorganic insulating film has a region in contact with the second inorganic insulating film in the peripheral region, an end part of the sealing film protective layer is arranged directly above the second inorganic insulating film in the peripheral region, and the adhesive member contacts with the end part of the sealing film protective layer, an end part of the first inorganic insulating film and an end part of the second inorganic insulating film in the peripheral region.

A display device in an embodiment according to the present invention includes a first substrate, a second substrate opposed to the first substrate, a display region between the first substrate and the second substrate, a touch sensor between the display region and the second substrate, a peripheral region outside the display region between the first substrate and the second substrate, an adhesive member arranged in the peripheral region adhering the first substrate and the second substrate, an interlayer insulating film between the first substrate and the second substrate, a light emitting element arranged in the display region, a sealing film between the interlayer insulating film and the second substrate, the light emitting element and the interlayer insulating film arranged between the sealing film and the first substrate; and a sealing film protective layer between the sealing film and the second substrate, the adhesive member arranged between the sealing film protective layer and the second substrate. The touch sensor is arranged between the sealing film protective layer and the sealing film, the touch sensor includes a first electrode, an insulating film, and a second electrode, the sealing film includes a first inorganic insulating film, an organic insulating film, and a second inorganic insulating film, the sealing film protective layer has a region in contact with an end part of the second inorganic insulating film in the peripheral region, the first inorganic insulating film has a region in contact with the second inorganic insulating film in the peripheral region, and the adhesive member does not overlap an end part of the sealing film protective layer in the peripheral region.

### BRIEF DESCRIPTION OF DRAWINGS

FIG. 1 is a schematic view showing a structure of a display device related to one embodiment of the present invention;

FIG. 2 is a cross-sectional view taken along the line A1-A2 in FIG. 1;

FIG. 3 is a cross-sectional view taken along the line B1-B2 in FIG. 1;

FIG. 4 is a cross-sectional view showing a display device related to one embodiment of the present invention;

FIG. 5 is a diagram for explaining a manufacturing process of a display device related to one embodiment of the present invention;

FIG. 6 is a diagram for explaining a manufacturing process of a display device related to one embodiment of the present invention;

FIG. 7 is a diagram for explaining a manufacturing process of a display device related to one embodiment of the present invention;

FIG. 8 is a schematic view showing a structure of a display device related to one embodiment of the present invention;

FIG. 9 is a cross-sectional view showing a display device related to one embodiment of the present invention;

FIG. 10 is a schematic view showing a structure of a display device related to one embodiment of the present invention;

FIG. 11 is a top view showing a structure of a display device related to one embodiment of the present invention;

FIG. 12 is a cross-sectional view showing a display device related to one embodiment of the present invention;

FIG. 13 is a cross-sectional view showing a display device related to one embodiment of the present invention;

FIG. 14 is a cross-sectional view showing a display device related to one embodiment of the present invention;

FIG. 15 is a diagram showing a crystal particle diameter of a transparent conductive electrode; and

FIG. 16 is a diagram showing a crystal particle diameter of a transparent conductive electrode.

### DESCRIPTION OF EMBODIMENTS

Each embodiment of the present invention is explained below while referring to the diagrams. However, it is possible to perform the present invention using many different forms within a scope that does not depart from the intention of the invention and the present invention should not be limited to the content described in the embodiments exemplified herein. In addition, although the width, thickness and shape of each component are shown schematically compared to their actual form in order to better clarify explanation, the drawings are merely an example and should not limit an interpretation of the present invention. Furthermore, in the specification and each drawing, the same reference symbols are attached to similar elements and elements that have been mentioned in previous drawings, and therefore a detailed explanation may be omitted where appropriate.

In the present invention, when a plurality of films is formed by processing one film, the plurality of films may have functions or roles different from each other. However, the plurality of films originates from a film formed as the same layer in the same process and has the same layer structure and the same material. Therefore, the plurality of films is defined as films existing in the same layer.

Furthermore, in the present specification, expressions such as “above”, “below” when explaining the diagrams express a relative relationship between a structure focused on and other structures. In the present specification, a direction from a first substrate towards a pixel electrode in a side surface view is defined as “above” and the reverse direction is defined as “below”. In the present specification and scope of the patent claims, when expressing a form in which a certain structure is arranged above another certain structure, as long as there is no particular limitation, these include parts which are not only directly above other parts or regions but also in an upper direction. That is, in the case where certain parts or regions are given as “above” other parts or regions, other structural elements may be included between other parts or regions in an upper direction.

### First Embodiment

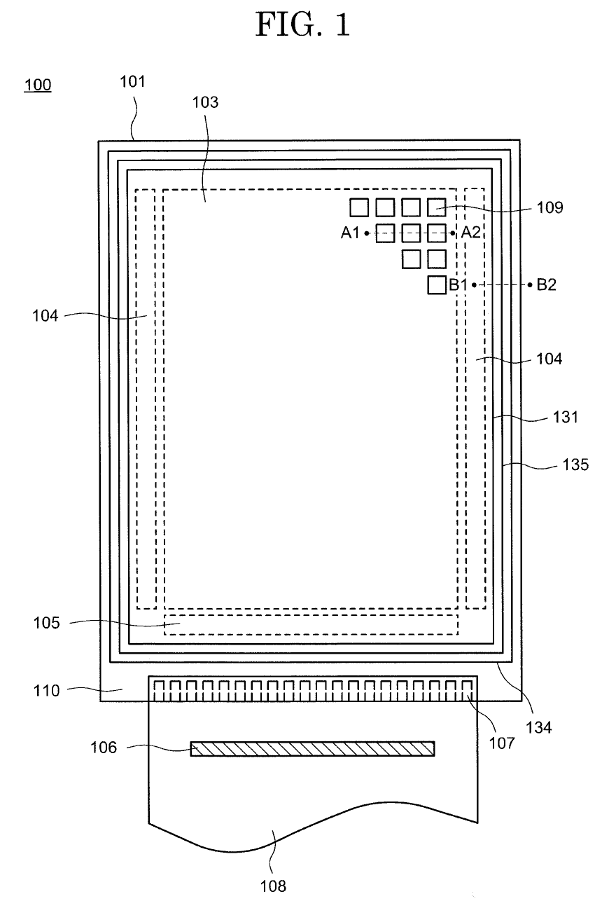

FIG. 1 is a schematic view showing a structure of a display device 100 according to one embodiment of the present invention, and shows a schematic structure in the case when the display device 100 is seen in a planar view. In the present specification, a state of the display device 100 when viewed from a direction perpendicular to a screen (display region) is referred to as “planar view”.

As shown in FIG. 1, the display device 100 includes a display region 103, a scanning line drive circuit 104, a data line drive circuit 105 and a driver IC 106 formed above an insulating surface. The driver IC 106 functions as a control part which provides signals to the scanning line driving circuit 104 and the data line driving circuit 105. The data line driving circuit 105 may be incorporated within the driver IC 106. Although the driver IC 106 is arranged on a flexible printed substrate 108, it may also be arranged above a first substrate 101. The flexible printed substrate is connected to a terminal 107 arranged above in a periphery region 110.

Here, the insulating surface is the top surface of the first substrate 101. The first substrate 101 supports each layer such as a pixel electrode and an insulating layer arranged above the surface thereof. Furthermore, the first substrate 101 itself may be made of an insulating material and may have an insulating surface or a separate insulating film may be formed on the first substrate 101 to form an insulating surface. The material of the first substrate 101 and the material forming the insulating film are not particularly limited as long as an insulating surface can be obtained.

In the display region 103 shown in FIG. 1, a plurality of pixels 109 are arranged in a matrix. Each of the pixels 109 includes a light-emitting element constituted a pixel electrode (anode), an organic layer (light-emitting section) including a light-emitting layer stacked on the pixel electrode, and a common electrode (cathode). A data signal corresponding to image data is supplied to each pixel 109 from the data line driving circuit 105. A transistor electrically connected to the pixel electrode arranged in each pixel 109 is driven according to these data signals and screen display can be performed according to the image data. Typically, a thin film transistor (TFT) can be used as the transistor. However, it is not limited to a thin film transistor and any element may be used as long as it has a current control function.

As shown in FIG. 1, a first inorganic insulating layer 131 is arranged above the display region 103. The first inorganic insulating layer 131 functions as a sealing film for preventing the entry of moisture or oxygen into a light emitting element. The first inorganic insulating layer 131 has an end part in the periphery region 110 on the outer side of the display region 103. A sealing film protection layer 134 is arranged above the first inorganic insulating layer 131. The sealing film protection layer 134 has an end part on the outer side of the end part of the first inorganic insulating layer 131 in the periphery region 110 on the outer side of the display region 103. An adhesive material 135 is arranged above the sealing film protective layer 134. The adhesive material 135 does not overlap the end part of the sealing film protective layer 134.

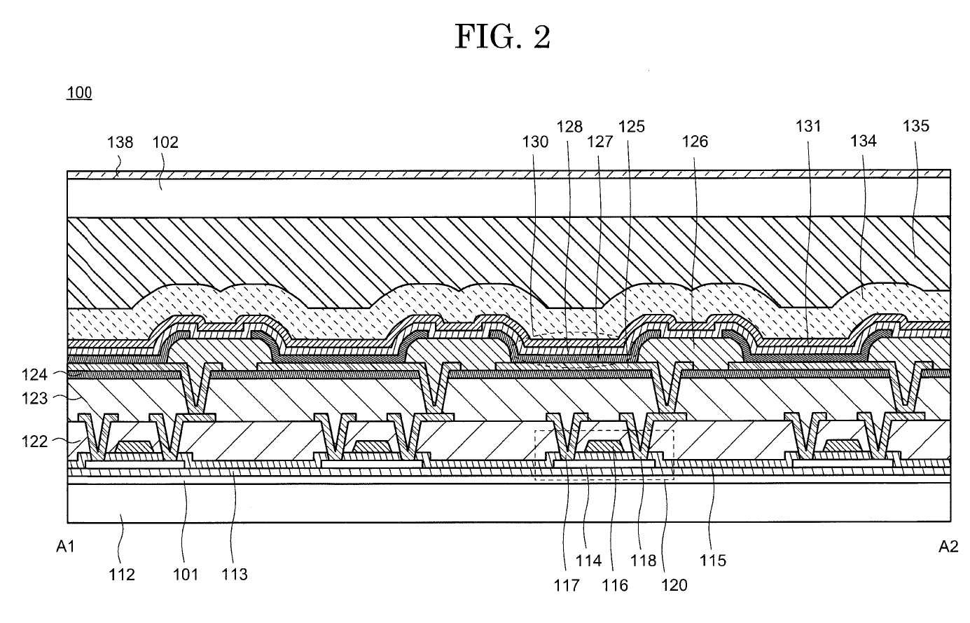

FIG. 2 is a diagram showing an example of a structure of a pixel in the display device 100 according to the first embodiment. Specifically, FIG. 2 is a diagram showing a structure of a cross section cut taken along the line A1-A2 of the display region 103 shown in FIG. 1. FIG. 2 shows a cross section of three light emitting elements 130 as a part of the display region 103. Although three light emitting elements 130 are exemplified in FIG. 2, actually, in the display region 103, several million or more light emitting elements are arranged in a matrix corresponding to the pixels.

As shown in FIG. 2, the display device 100 includes a first substrate 101, a second substrate 112, and a counter substrate 102. A glass substrate, a quartz substrate, a flexible substrate (polyimide, polyethylene terephthalate, polyethylene naphthalate, triacetyl cellulose, cyclic olefin copolymer, cycloolefin polymer, and a resin substrate having flexibility) can be used as the first substrate 101, the second substrate 112, and the counter substrate 102. In the case when it is not necessary for the first substrate 101, the second substrate 112, and the counter substrate 102 to have translucency, it is also possible to use a metal substrate, a ceramic substrate or a semiconductor substrate. In the present embodiment, a case where polyimide is used as the first substrate 101 and polyethylene terephthalate is used as the second substrate 112 and the counter substrate 102 is explained.

A base film 113 is arranged above the first substrate 101. The base film 113 is an insulating layer formed from an inorganic material such as silicon oxide, silicon nitride, aluminum oxide or the like. The base film 113 is not limited to a single layer and may have a stacked structure in which, for example, a silicon oxide layer and a silicon nitride layer are combined. This structure may be appropriately determined considering adhesion to the first substrate 101 and gas barrier properties to the transistor 120 described later.

A transistor 120 is arranged above the base film 113. The structure of the transistor 120 may be a top gate type or a bottom gate type structure. In this embodiment, the transistor 120 includes a semiconductor layer 114 arranged above the base film 113, a gate insulating film 115 covering the semiconductor layer 114, and a gate electrode 116 arranged above the gate insulating film 115. In addition, an interlayer insulating film 122 covering the gate electrode 116 is arranged above the transistor 120, a source electrode or drain electrode 117 and a source electrode or drain electrode 118 connected to the semiconductor layer 114 are each arranged above the interlayer insulating film 122. Furthermore, in this embodiment, although an example is explained in which the interlayer insulating film 122 has a single layer structure, the interlayer insulating film 122 may also have a stacked structure.

Furthermore, the material of each layer which forms the transistor 120 may be any known material and is not particularly limited. For example, generally, polysilicon, amorphous silicon, or an oxide semiconductor can be used as the semiconductor layer 114. Silicon oxide or silicon nitride can be used as the gate insulating film 115. The gate electrode 116 is formed from a metal material such as copper, molybdenum, tantalum, tungsten, or aluminum. Silicon oxide or silicon nitride can be used as the interlayer insulating film 122. The source electrode or drain electrode 117 and the source electrode or drain electrode 118 are each formed from a metal material such as copper, titanium, molybdenum, or aluminum.

Furthermore, although not shown in FIG. 2, it is possible to arrange a first wiring made of the same metal material as the metal material forming the gate electrode 116 in the same layer as the gate electrode 116. The first wiring can be arranged as, for example, a scanning line driven by the scanning line driving circuit 104 or the like. Although not shown in FIG. 2, a second wiring extending in a direction intersecting the first wiring can be arranged in the same layer as the source electrode or drain electrode 117 and the source electrode or drain electrode 118. The second wiring can be arranged, for example, as a data line or the like driven by the data line driving circuit 105.

A planarization film 123 is arranged above the transistor 120. The planarization film 123 is formed including an organic resin material. For example, known organic resin materials such as polyimide, polyamide, acrylic, or epoxy and the like can be used as the organic resin material. These materials are capable of forming a film by a solution coating method and have a feature of highly flattening effect. Although not specifically shown in the diagram, the planarization film 123 is not limited to a single layer structure and may also have a stacked structure of a layer containing an organic resin materials and an inorganic insulating layers.

The planarization film 123 includes a contact hole exposing a part of the source electrode or drain electrode 118. The contact hole is an opening part for electrically connecting a pixel electrode 125 described later and the source electrode or drain electrode 118. Therefore, the contact hole is arranged to overlap a part of the source electrode or the drain electrode 118. The source or drain electrode 118 is exposed at the bottom surface of the contact hole.

A protective film 124 is arranged above the planarization film 123. The protective film 124 overlaps the contact hole formed in the planarization film 123. The protective film 124 preferably has barrier properties against moisture and oxygen and is formed using, for example, an inorganic insulating material such as a silicon nitride film or aluminum oxide.

A pixel electrode 125 is arranged above the protective film 124. The pixel electrode 125 overlaps the contact hole of the planarization film 123 and the protection film 124 and is electrically connected to the source electrode or drain electrode 118 exposed at the bottom surface of the contact hole. In the display device 100 of the present embodiment, the pixel electrode 125 functions as an anode which forms a light emitting element 130. The pixel electrode 125 has a different structure depending on whether it is a top emission type or a bottom emission type. For example, in the case of a top emission type, it is preferred to use a metal film having a high reflectance as the pixel electrode 125 or a stacked structure of a high transparent conductive film having a high work function such as an indium oxide transparent conductive film (for example ITO) or a zinc oxide transparent conductive film (for example IZO, ZnO) and a metal film. In the case of a bottom emission type structure, the transparent conductive film described above is used as the pixel electrode 125. In the present embodiment, a top emission type organic EL display device is explained as an example. An end part of the pixel electrode 125 is covered by a first insulating layer 126 described later.

A first insulating layer 126 formed from an organic resin material is arranged above the pixel electrode 125. A known resin material such as polyimide, polyamide, acrylic, epoxy or siloxane can be used as the organic resin material. The first insulating layer 126 has an opening part in a part above the pixel electrode 125. The first insulating layer 126 is arranged to cover the end part (edge part) of the pixel electrode 125 between mutually adjacent pixel electrodes 125, and functions as a member separating adjacent pixel electrodes 125. As a result, the first insulating layer 126 is also generally called a “partition wall” or “bank”. A part of the pixel electrode 125 exposed from the first insulating layer 126 serves as a light emitting region of the light emitting element 130. It is preferred that the inner wall of the opening part of the first insulating layer 126 has a tapered shape. In this way, it is possible to reduce coverage defects at the end part of the pixel electrode 125 when forming a light emitting layer described herein. The first insulating layer 126 may not only cover the end part of the pixel electrode 125 but can also function as a filling material filling a concave part caused by a contact hole in the planarization film 123 and the protective film 124.

An organic layer 127 is arranged above the pixel electrode 125. The organic layer 127 has at least a light emitting layer formed from an organic material and functions as a light emitting part of the light emitting element 130. In addition to the light emitting layer, the organic layer 127 may also include various charge transport layers such as an electron injection layer, an electron transport layer, a hole injection layer and a hole transport layer. The organic layer 127 is arranged to cover a light emitting region, that is, to cover an opening part of the first insulating layer 126 in the light emitting region and the opening part of the first insulating layer 126.

Furthermore, in the present embodiment, a structure is adopted which displays each color of RGB by arranging a light emitting layer which emits light of a desired color in the organic layer 127 and forming the organic layer 127 having different light emitting layers above each pixel electrode 125. That is, in the present embodiment, the light emitting layer of the organic layer 127 is discontinuous between adjacent pixel electrodes 125. In addition, various charge transport layers are continuous between adjacent pixel electrodes 125. A known structure or a known material can be used for the organic layer 127 and is not particularly limited to the structure of the present embodiment. In addition, the organic layer 127 has a light emitting layer which emits white light, and each color of RGB may be displayed through a color filter. In this case, the organic layer 127 may also be arranged above the first insulating layer 126.

A counter electrode 128 is arranged above the organic layer 127 and the first insulating layer 126. The counter electrode 128 functions as a cathode which forms the light emitting element 130. Since the display device 100 of the present embodiment is a top emission type, a transparent electrode is used as the counter electrode 128. An MgAg thin film or a transparent conductive film (ITO or IZO) is used as the thin film forming the transparent electrode. The counter electrode 128 is also arranged above the first insulating layer 126 across each pixel 109. The counter electrode 128 is electrically connected to an external terminal via a lower layer conductive layer in the periphery region in the vicinity of the end part of the display region 103. As described above, in the present embodiment, the light emitting element 130 is formed by a part (anode) of the pixel electrode 125 exposed from the first insulating layer 126, the organic layer 127 (light emitting part) and the counter electrode 128 (cathode).

As shown in FIG. 2, the first inorganic insulating layer 131 is arranged above the display region 103. The first inorganic insulating layer 131 functions as a sealing film for preventing moisture and oxygen from entering the light emitting element 130. By arranging the first inorganic insulating layer 131 above the display region 103, it is possible to prevent moisture and oxygen from entering the light emitting element 130 and thereby improve the reliability of the display device. For example, it is possible to use a film such as silicon nitride (SixNy), silicon oxynitride (SiOxNy), silicon nitride oxide (SiNxOy), aluminum oxide (AlxOy), aluminum nitride (AlxNy), aluminum oxynitride (AlxOyNz) or aluminum nitride oxide (AlxNyOz) or the like as the first inorganic insulating layer 131 (x, y, z are arbitrary).

A sealing film protective layer 134 is arranged above the first inorganic insulating layer 131. The sealing film protective layer 134 is arranged to prevent damage occurring to the sealing film (the first inorganic insulating layer 131 in FIG. 1 and FIG. 2) when bonding the first substrate 101 and the counter substrate 102. As a film formation method of the sealing film protective layer 134, first, an organic resin is applied by an inkjet method or a dispenser method. Following this, the sealing resin protective layer 134 is formed by curing the organic resin by ultraviolet rays or heat. Acrylic, epoxy or the like can be used as the sealing film protective layer 134. By using an inkjet method or dispenser method, it is possible to prevent the sealing film from being damaged when applying the organic resin onto the first inorganic insulating layer 131.

From the second substrate 112 explained above to the sealing film protective layer 134 are collectively called an array substrate in the present embodiment.

An adhesive material 135 is arranged on the sealing film protective layer 134. For example, an acrylic type, rubber type, silicone type, urethane type adhesive material can be used as the adhesive material 135. In addition, the adhesive material 135 may also include moisture absorbing substances such as calcium and zeolite. By including a moisture absorbing substance in the adhesive material 135, even when moisture enters into the display device 100, it is possible to delay the arrival of moisture to the light emitting element 130. In addition, a spacer may be arranged in the adhesive material 135 in order to secure a gap between the first substrate 101 and the counter substrate 102. This spacer may be mixed with the adhesive material 135 or may be formed of a resin and the like on the first substrate 101.

An overcoat layer for flattening for example may be arranged on the counter substrate 102. In the case where the organic layer 127 emits white light, the counter substrate 102 is arranged with a color filter corresponding to each color of RGB on the main surface (surface facing the first substrate 101) and a black matrix may be arranged between the color filters. In the case where a color filter is not formed on the counter substrate 102 side, for example, a color filter may be directly formed on the sealing film or the sealing film protective layer 134, and the adhesive material 135 may be formed thereon. In addition, a polarization plate 138 is arranged on the rear surface (display surface side) of the counter substrate 102.

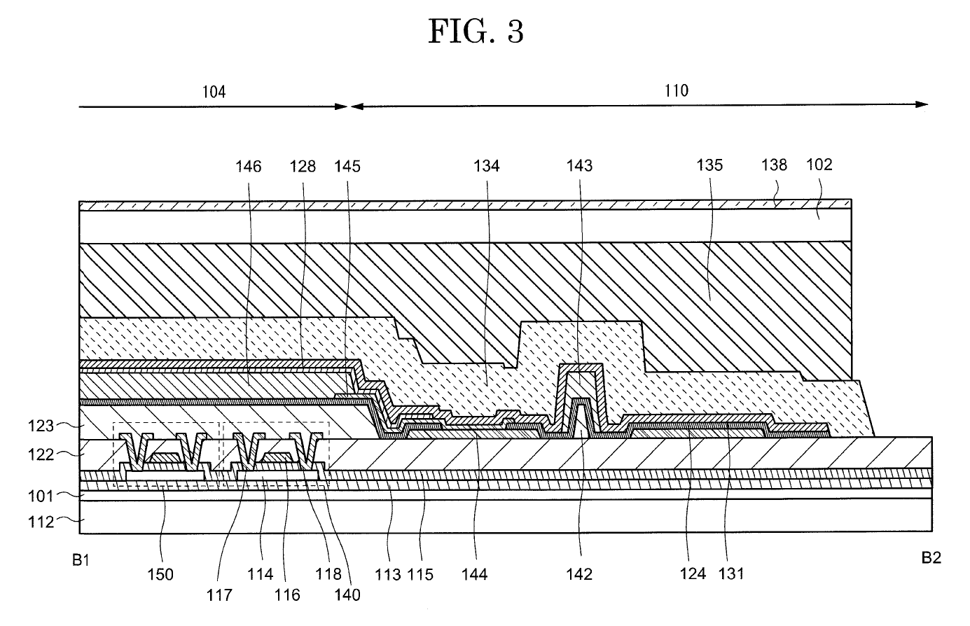

FIG. 3 shows a cross-sectional view taken along the line B1-B2 shown in FIG. 1. Specifically, FIG. 3 is a cross-sectional view of the scanning line driving circuit 104 and the periphery region 110 on the outer side of the display region 103.

In FIG. 3, a first substrate 101 is arranged above a second substrate 112. A transistor 140 and a transistor 150 are arranged above the first substrate 101 with a base film 113 interposed therebetween. A scanning line driving circuit 104 is formed by a plurality of transistors including the transistor 140 and the transistor 150. Furthermore, the transistor 140 and the transistor 150 may have the same polarity or a CMOS structure having different polarities. An interlayer insulating film 122 is formed above the transistor 140 and the transistor 150 the same as the display region 103. A contact hole is formed in the interlayer insulating film 122 and source electrodes or drain electrodes 117 and 118 are connected to a semiconductor layer 114 of the transistor 140 via the contact holes. In addition, wiring 144 is arranged above the interlayer insulating film 122 in the periphery region 110. The wiring 144 is formed from the same film as the source electrodes or drain electrodes 117 and 118.

A planarization film 123 is arranged above the interlayer insulating film 122 in the scanning line driving circuit 104. In addition, the planarization film 123 has an end part in the periphery region 110. In addition, a first convex part 142 is arranged above the interlayer insulating film 122 in the periphery region 110. The first convex part 142 is formed from the same film as the planarization film 123.

A protective film 124 is arranged above the planarization film 123. The protective film 124 is arranged in contact with an end part of the planarization film 123. The protective film 124 is preferred to have barrier properties against moisture and oxygen. By arranging the protective film 124 in contact with the end part of the planarization film 123, it is possible to prevent moisture and oxygen from entering from the end part of the planarization film 123. In addition, by arranging the protective film 124 in contact with the interlayer insulating film 122 and the wiring 144, it is possible to prevent moisture and oxygen from entering through a gap between the protective film 124 and the interlayer insulating film 122.

An opening part is arranged in the protective film 124, and the wiring 144 is connected to an electrode 145 via the opening part. The electrode 145 is formed from the same film as the pixel electrode 125 of the light emitting element 130. A first insulating layer 146 is arranged above the protective film 124 and the electrode 145. The first insulating layer 146 includes an end part in a region overlapping with the planarization film 123. In addition, a second convex part 143 is arranged via the protective film 124 in the region overlapping with the first convex part 142. The first insulating layer 146 and the second convex part 143 are formed from the same film as the first insulating layer 126.

A counter electrode 128 is arranged above the first insulating layer 146. The counter electrode 128 is formed to cover the entire surface of the display region 103 and the scanning line driving circuit 104. Next, a section where the counter electrode 128 is connected to the electrode 145 serves as a cathode contact. In addition, the electrode 145 is connected to the wiring 144 through an opening part formed in the protective film 124. The cathode contact is arranged to surround the display region 103 and the scanning line driving circuit 104 in the periphery region 110 in order to prevent the resistance of the cathode from rising. In addition, the wiring 144 is similarly arranged to surround the display region 103 and the scanning line driving circuit 104 in the periphery region 110. By arranging a plurality of cathode contacts intermittently, the cathode contact may surround the display region 103 and the scanning line driving circuit 104. Furthermore, although an example is exemplified in which the cathode contact between the counter electrode 128 and the electrode 145 is arranged in the periphery region 110, it may also be arranged in a region between the display region 103 and the scanning line driving circuit 104. In addition, by arranging the counter electrode 128 in contact with an end part of the first insulating layer 146, it is possible to prevent moisture and oxygen from entering from the end part of the first insulating layer 126.

A first inorganic insulating layer 131 is arranged as a sealing film above the protective film 124 and the counter electrode 128. The first inorganic insulating layer 131 is arranged to prevent moisture and oxygen from entering the light emitting element 130 in the display region 103. The first inorganic insulating layer 131 is arranged in contact with the protective film 124 in the periphery region 110. Since the first inorganic insulating layer 131 and the protective film 124 are each formed from an inorganic insulating material, it is possible to improve adhesion. The protective film 124 is arranged to cover an end part of the planarization film 123 and an end part of the first insulating layer 146. It is preferred that the end part of the planarization film 123 and the end part of the first insulating layer 146 which are formed of an organic resin and serve as an entry path for moisture and oxygen are covered by the first inorganic insulating layer 131.

A sealing film protective layer 134 is arranged above the first inorganic insulating layer 131. It is preferred that the sealing film protective layer 134 covers at least the end part of the planarization film 123 and the end part of the first insulating layer 146. This is because when foreign matter exists above the end part of the planarization film 123 and the end part of the first insulating layer 146, it is easier for the first inorganic insulating layer 131 to be damaged when the counter substrate 102 is bonded. If moisture or oxygen enters from damage generated in the first inorganic insulating layer 131, this leads to deterioration of the light emitting element 130. The sealing film protective layer 134 is arranged in contact with the end part of the protective film 124 and the end part of the first inorganic insulating layer 131. The thickness of the sealing film protective layer 134 is preferred to be 1 μm or more and 10 μm or less. In addition, the adhesive material 135 arranged above the sealing film protective layer 134 does not overlap with the end part of the sealing film protective layer 134.

In a conventional manufacturing method of a display device, when foreign matter is sandwiched between a substrate on which a light emitting element is formed and a counter substrate which are bonded via the adhesive, pressure due to bonding causes damage to a sealing film which was a problem. In particular, if foreign matter exists above the planarization film 123 or the first insulating layer 126, damage easily occurs in the sealing film. When damage to the sealing film occurs, moisture or oxygen enters from this damage and when it reaches the light emitting element, the light emitting element may deteriorate. In addition, when the light emitting element deteriorates, reliability of the display device deteriorates.

As shown in FIG. 3, the sealing film protective layer 134 is arranged above the first inorganic insulating layer 131 which functions as a sealing film. In this way, even when foreign matter is sandwiched between the first substrate 101 and the counter substrate 102 which are bonded with the adhesive 135, it is possible to protect the first inorganic insulating layer 131 from the foreign matter by the sealing film protective layer 134. As a result, since it is possible to prevent damage to the first inorganic insulating layer 131, entry of moisture or oxygen from such damage can be prevented. In addition, since deterioration of the light emitting element 130 in the display region 103 can be prevented, reliability of the display device can be improved.

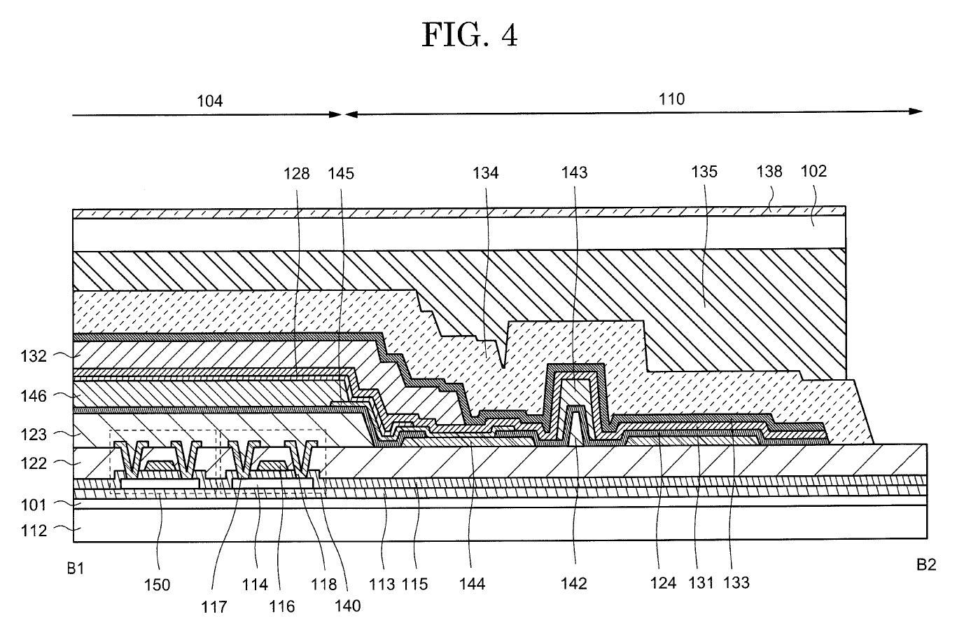

Next, a display device partially different from the display device shown in FIG. 3 is shown in FIG. 4. In the display device shown in FIG. 4, the structure of the sealing film is partially different from the sealing film shown in the display device shown in FIG. 3. Since the other structures are the same as in FIG. 3, a detailed description thereof is omitted.

In the display device shown in FIG. 4, the sealing film has a three layer structure includes a first inorganic insulating layer 131, an organic insulating layer 132 and a second inorganic insulating layer 133. The first inorganic insulating layer 131 is similar to the first inorganic insulating layer 131 shown in FIG. 3. In FIG. 4, the organic insulating layer 132 is arranged above the first inorganic insulating layer 131 to cover the end part of the planarization film 123 and the end part of the first insulating layer. In addition, the second inorganic insulating layer 133 is arranged above the first inorganic insulating layer 131 and the organic insulating layer 132. The second inorganic insulating layer 133 is in contact with the first inorganic insulating layer 131 in a region where the organic insulating layer 132 is not formed.

The first inorganic insulating layer 131 and the second inorganic insulating layer 133 can be formed using a film such as silicon nitride (SixNy), silicon oxynitride (SiOxNy), silicon nitride oxide (SiNxOy), aluminum oxide (AlxOy), aluminum nitride (AlxNy), aluminum nitride (AlxOyNz)) and aluminum nitride oxide (AlxNyOz) or the like (x, y, z are arbitrary). In addition, it is possible to use a polyimide resin, an acrylic resin, an epoxy resin, a silicone resin, a fluororesin, a siloxane resin, or the like as the organic insulating layer 132. In FIG. 4, although a case is shown where the sealing film is formed by a three layer structure of the first inorganic insulating layer 131, the organic insulating layer 132, and the second inorganic insulating layer 133, the present invention is not limited to this structure. An inorganic insulating material and an organic insulating material may be combined to form a film of four or more layers as the sealing film.

As shown in FIG. 4, it is possible to improve adhesin when the first inorganic insulating layer 131 and the second inorganic insulating layer 133 are in contact with each other. In addition, by arranging the first convex part and the second convex part in the peripheral region 110, it is possible to increase the region where the first inorganic insulating layer 131 and the second inorganic insulating layer 133 are in contact with each other. In this way, it possible to prevent peeling of the first inorganic insulating layer 131 and the second inorganic insulating layer 133. In addition, it is possible to prevent the entrance of moisture or oxygen from the exterior of the display device. Furthermore, since the first inorganic insulating layer 131 is arranged in contact with the protective film 124, adhesion between the first inorganic insulating layer 131 and the protective film 124 can be improved.

As shown in FIG. 4, the sealing film protective layer 134 includes a region in contact with an end part of the first inorganic insulating layer 131 and an end part of the second inorganic insulating layer 133. In addition, the adhesive material 135 arranged on the sealing film protective layer 134 does not overlap with the end part of the sealing film protective layer 134.

As shown in FIG. 4, the sealing film protective layer 134 is arranged above the first inorganic insulating layer 131, the organic insulating layer 132, and the second inorganic insulating layer 133 which function as a sealing film. In this way, even when foreign matter is sandwiched between the first substrate 101 and the counter substrate 102 which are bonded together with the adhesive 135, it is possible to protect the second inorganic insulating layer 133 from the foreign matter by the sealing film protective layer 134. As a result, since damage to the second inorganic insulating layer 133 can be prevented, the entrance of moisture or oxygen from such damage can be prevented. In addition, since deterioration of the light emitting element 130 in the display region 103 can be prevented, reliability of the display device can be improved.

In addition, by using a flexible material as the first substrate 101, the second substrate 112 and the counter substrate 102, a display device capable of bending can be obtained. In this case, by sandwiching the organic insulating layer 132 between the first inorganic insulating layer 131 and the second inorganic insulating layer 133, stress caused by bending of the display device can be relieved. In this way, damage to the sealing film due bending of the display device can be prevented, and the entrance of moisture and oxygen can be prevented. As a result, moisture or oxygen can be prevented from entering the light emitting element 130 in the display region 103, and thereby reliability of the display device can be improved. Furthermore, it needless to say that a sealing film is formed in the display region 103 in which the organic insulating layer 132 is sandwiched between the first inorganic insulating layer 131 and the second inorganic insulating layer 133 above each of the light emitting elements 130 and the first insulating layer 126.

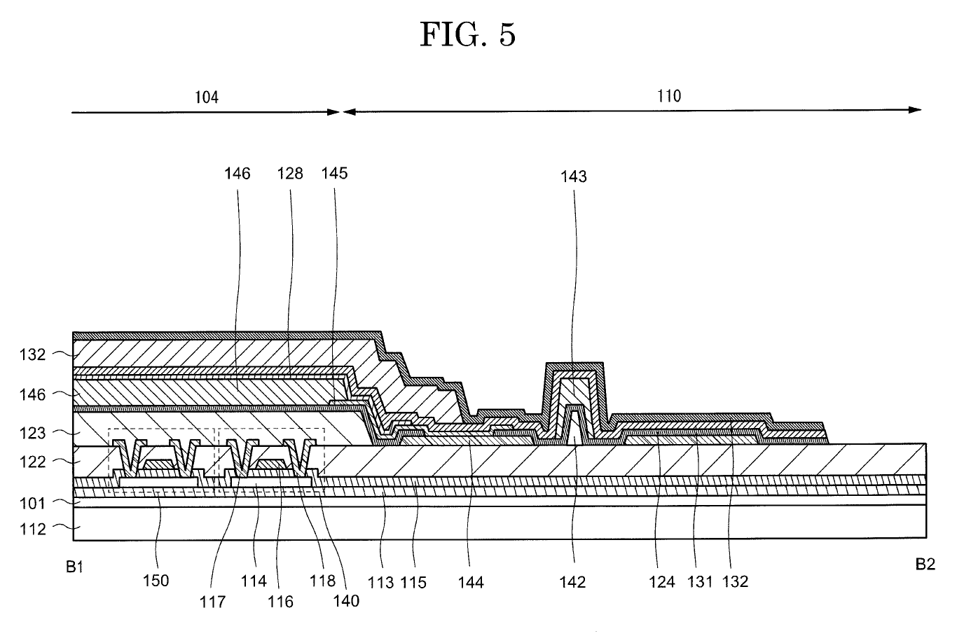

Next, a manufacturing method of the display device 100 shown in FIG. 4 is explained while referring to FIG. 5 to FIG. 7. FIG. 5 to FIG. 7 are cross-sectional views of the scanning line driving circuit 104 and the periphery region 110 on the outer side of the display region 103.

First, as shown in FIG. 5, a base film 113 is formed above a first substrate 101 formed above a support substrate 141. In the present embodiment, a case is explained where a glass substrate is used as the support substrate and polyimide is used as the first substrate 101. Next, a transistor 140 and a transistor 150 are formed above over the base film 113. Next, an interlayer insulating film 122 is formed above the transistor 140 and the transistor 150. An opening is formed in the interlayer insulating film 122, and a source electrode or a drain electrode connected via the opening of the interlayer insulating film 122 is formed. In addition, wiring 144 is formed using the same film as the source electrodes or drain electrodes 117 and 118.

Next, a planarization film 123 is formed above the interlayer insulating film 122, the source electrodes or drain electrodes 117 and 118. The planarization film 123 is formed in a region where the scanning line driving circuit 104 is formed. In addition, a first convex part 142 is formed using the same film as the planarization film 123.

Next, a protective film 124 is formed above the planarization film 123 and the first convex part 142. The protective film 124 is formed to cover an end part of the planarization film 123 which exists in the periphery region 110 and the first convex part 142. In the periphery region 110, it is preferred that the end part of the planarization film 123 and the protective film 124 are in contact with each other. In addition, it is preferred that the interlayer insulating film 122 and the protective film 124 are in contact with each other. By arranging the end part of the planarization film 123 and the protection film 124 in contact with each other, it is possible to prevent moisture and oxygen from entering from the end part of the planarization film 123.

Next, an opening part is formed in the protective film 124, and next an electrode 145 is formed above the protective film 124. The electrode 145 is connected to the wiring 144 via the opening part of the protective film 125. The electrode 145 is formed using the same film as the pixel electrode 125 of the light emitting element 130 in the display region 103. Next, a first insulating layer 146 is formed above the electrode 145. The first insulating layer 146 is formed from the same film as the first insulating layer 126 in the display region 103. In addition, in the periphery region 110, a second convex part 143 is formed above the first convex part 142 via the protective film 124. The second convex part 143 is also formed from the same film as the first insulating layer 126. Next, a counter electrode 128 is formed above the first insulating layer 146. The counter electrode 128 is formed above the display region 103 and the scanning line driving circuit 104, and is connected to the electrode 145.

Next, a first inorganic insulating layer 131 is formed above the protective film 124 and the counter electrode 128. Next, an organic insulating layer 132 is formed above the first inorganic insulating layer 131. Next, a second inorganic insulating layer 133 is formed above the organic insulating layer 132. The first inorganic insulating layer 131, the organic insulating layer 132, and the second inorganic insulating layer 133 function as a sealing film.

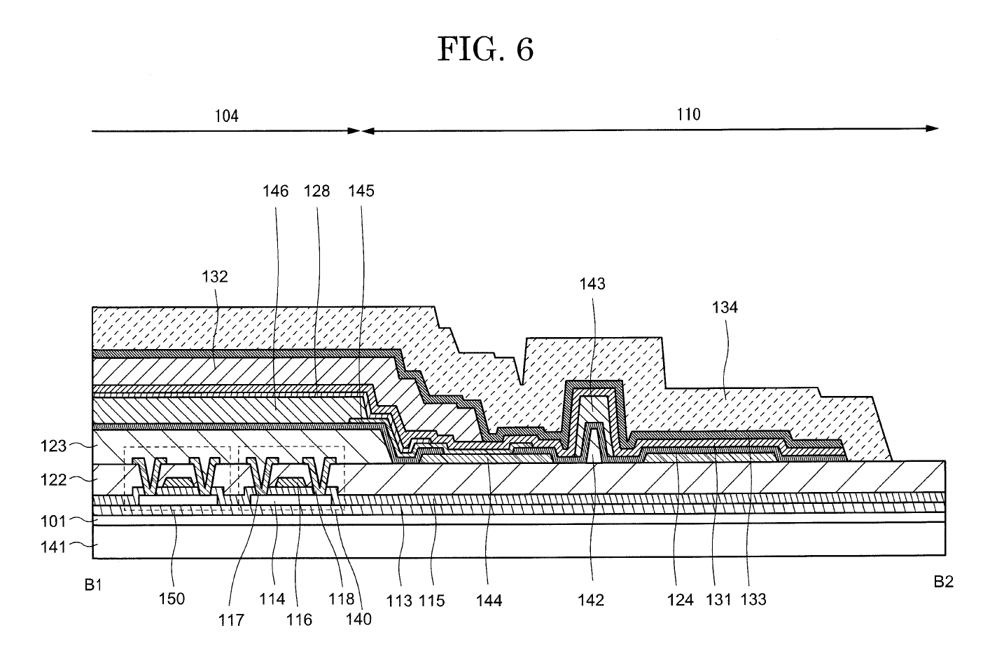

Next, as shown in FIG. 6, a sealing film protective layer 134 is formed above the second inorganic insulating layer 133. As a film formation method of the sealing film protective layer 134, first, an organic resin is applied by an inkjet method or a dispenser method. Subsequently, the sealing resin protective layer 134 is formed by curing the organic resin by ultraviolet rays or heat. Acrylic, epoxy, or the like can be used as the sealing film protective layer 134. By using an inkjet method or a dispenser method, it is possible to prevent the second inorganic insulating layer 133 from being damaged when applying the organic resin onto the second inorganic insulating layer 133.

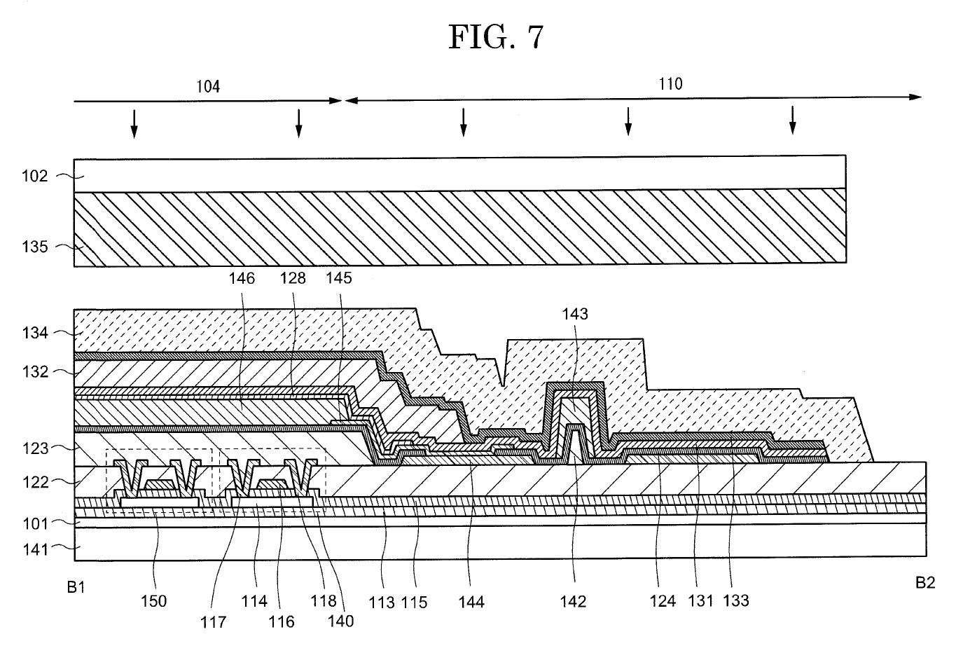

Next, as shown in FIG. 7, the counter substrate 102 and the first substrate 101 are bonded together via the adhesive material 135. For example, acrylic type, rubber type, silicone type, or urethane type adhesive materials can be used as the adhesive material 135. In addition, the adhesive material 135 may include moisture absorbing substances such as calcium and zeolite. By including a moisture absorbing substance in the adhesive material 135, even when moisture enters into the display device 100, it is possible to delay the arrival of moisture to the light emitting element 130.

In the display device disclosed in the present specification, the sealing film protective layer 134 is arranged above the sealing film which is arranged above the display region 103. In this way, even when foreign matter is sandwiched between the first substrate 101 and the counter substrate 102 which are bonded with the adhesive material 135, it is possible to protect the sealing film from the foreign matter by the sealing film protective layer 134. As a result, since it is possible to prevent damage to the sealing film, the entrance of moisture or oxygen due to such damage can be prevented. In addition, since deterioration of the light emitting element 130 in the display region 103 can be prevented, reliability of the display device can be improved.

Next, the first substrate 101 is peeled from the support substrate 141 by irradiating the first substrate 101 with a laser through the support substrate 141. Next, the second substrate 112 is bonded to the rear surface of the first substrate 101. Then, the polarization plate 138 is attached to the rear side of the counter substrate 102 and the display device 100 shown in FIG. 4 can be manufactured.

### Second Embodiment

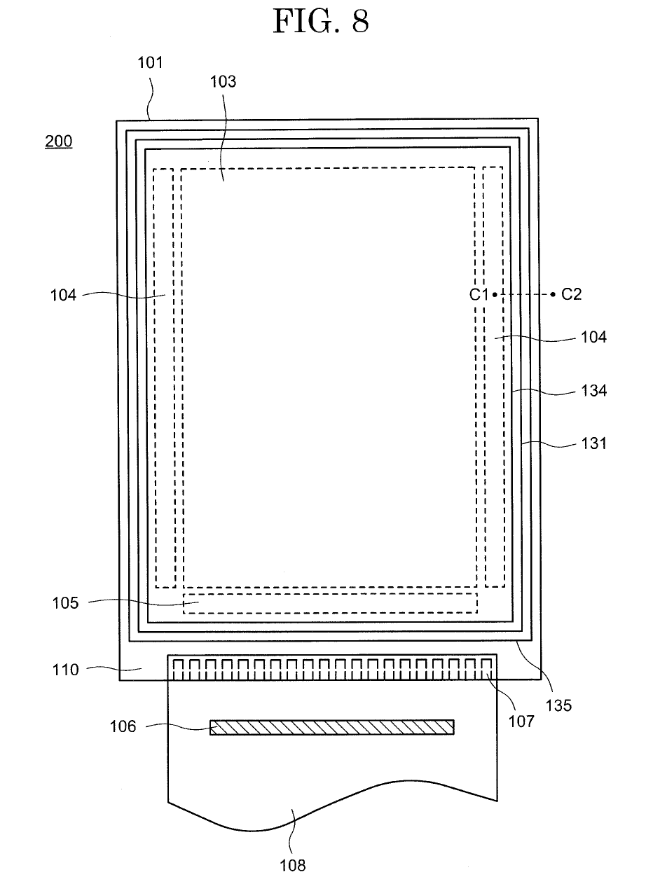

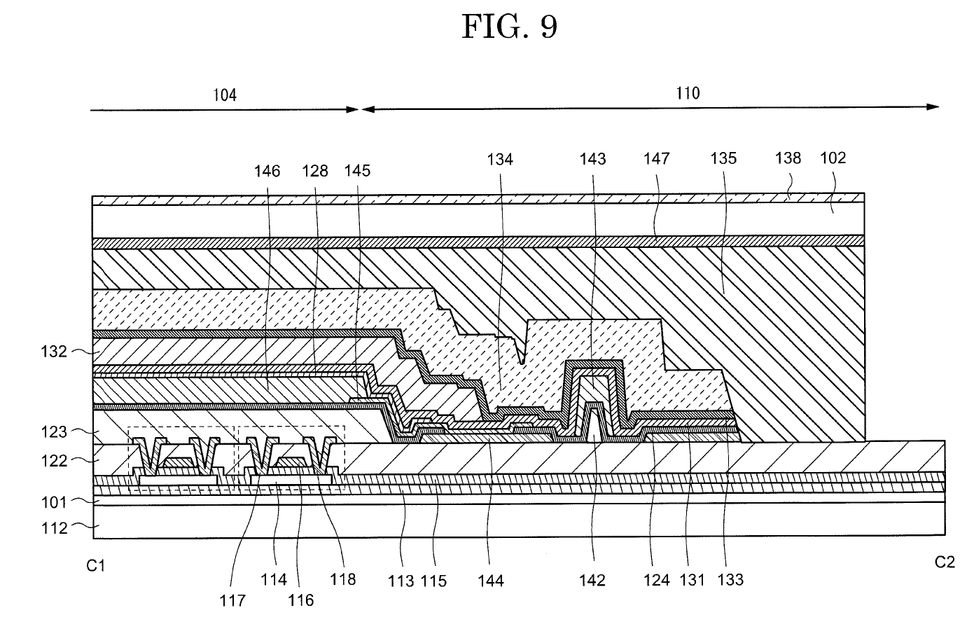

In the present embodiment, a display device having a structure partially different from the display device described in the First Embodiment is explained while referring to FIG. 8 and FIG. 9. In the present embodiment, the structure of the counter substrate which is bonded to an array substrate is different from that of the First Embodiment. In addition, the sealing film, the sealing film protective layer 134 and the counter substrate 102 are arranged. Since the other structures are the same as the structures of the display device illustrated in the other embodiments, a detailed explanation is omitted.

FIG. 8 is a schematic view showing a structure of a display device 200 according to one embodiment of the present invention, and shows a schematic structure in the case where the display device 200 is viewed in a planar view. As shown in FIG. 8, the first inorganic insulating layer 131 is arranged above the display region 103. In addition, the first inorganic insulating layer 131 has an end part in the periphery region 110 on the outer side of the display region 103. In addition, the sealing film protective layer 134 is arranged above the first inorganic insulating layer 131. Here, the difference from the display device 100 shown in FIG. 1 is that the end part of the sealing film protective layer 134 is located further to the inner side than the end part of the first inorganic insulating layer 131. In addition, the end part of the adhesive material 135 is located on the outer side of the end part of the sealing film protective layer 134 and the end part of the first inorganic insulating layer 131.

A cross-sectional view taken along the line C1-C2 shown in FIG. 8 is shown in FIG. 9. In the display device 200 shown in FIG. 9, a moisture proof film is used as a substrate which is bonded to an array substrate. The moisture proof film is formed by arranging a barrier layer 147 on the counter substrate 102 and by further combining the adhesive material 135 which has high moisture resistance. The barrier layer 147 is preferred to have a function of preventing permeation of moisture and oxygen. In this way, it is possible to prevent moisture and oxygen from entering the inside of the display device from above the counter substrate 102. For example, silicon nitride, aluminum oxide, or the like can be used as the barrier layer 147. In addition, it is preferred to use a material having low hygroscopicity among acrylic type, epoxy type and olefin type as the adhesive material 135. In addition, it is preferred that the adhesive material 135 includes a moisture absorbing substance. Calcium, zeolite and the like are included as the moisture absorbing substance. By including a moisture absorbing substance in the adhesive material 135, even when moisture enters into the display device 100, it is possible to delay the arrival of moisture to the light emitting element 130. The adhesive material 135 is preferred to have a higher moisture resistance compared to the sealing film protective layer 134. In this way, even if moisture or oxygen enters from the exterior of the display device 300, moisture or oxygen can be absorbed in the adhesive material 135. As a result, it is possible to prevent moisture and oxygen from reaching the light emitting element 130.

In addition, in the periphery region 110, the first inorganic insulating layer 131 includes a region which is in contact with the second inorganic insulating layer 133. In this way, adhesion between the first inorganic insulating layer 131 and the second inorganic insulating layer 133 can be improved. In addition, the first inorganic insulating layer 131 includes a region which is in contact with the protective film 124. Since the first inorganic insulating layer 131 and the protective film 124 are each formed from an inorganic insulating material, adhesion can be improved. This is preferred since moisture and oxygen can enter from the periphery region 110. In addition, by arranging the first convex part and the second convex part in the periphery region 110, it is possible to increase the region where the first inorganic insulating layer 131 and the second inorganic insulating layer 133 are in contact with each other. In this way, it possible to prevent peeling of the first inorganic insulating layer 131 and the second inorganic insulating layer 133.

It is preferred that the sealing film protective layer 134 covers at least the end part of the planarization film 123 and the end part of the first insulating layer 146. This is because damage to the sealing film easily occurs when adhering the counter substrate 102 in the case where foreign matter exists above the end part of the planarization film 123 and the end part of the first insulating layer 146. When moisture or oxygen enters from damage generated in the sealing film, such damage leads to deterioration of the light emitting element 130. In addition, it is preferred that the end part of the sealing film protective layer 134 is covered by the adhesive material 135. In this way, it is possible to prevent moisture and oxygen from entering from the end part of the sealing film protective layer 134. It is also preferred that the end part of the first inorganic insulating layer 131 and the end part of the second inorganic insulating layer 133 are also covered by the adhesive material 135 which has high moisture proof properties.

In the display device shown in FIG. 9, the sealing film protective layer 134 is arranged above the sealing film which is arranged above the display region 103. In this way, even when foreign matter is sandwiched between the first substrate 101 and the counter substrate 102 which are bonded with the adhesive material 135, it is possible to protect the sealing film from the foreign matter by the sealing film protective layer 134. As a result, since damage to the sealing film can be prevented, the entrance of moisture or oxygen from such damage can be prevented. In addition, since deterioration of the light emitting element 130 in the display region 103 can be prevented, reliability of the display device can be improved. Furthermore, it is desirable that the sealing film protective layer 134 also covers an end part of the organic insulating layer 132. Even when foreign matter is sandwiched in the vicinity of the end part of the organic insulating layer 132 when the first substrate 101 and the counter substrate 102 are bonded together with the adhesive material 135, the sealing film can be protected from the foreign matter by the sealing film protective layer 134. By arranging the sealing film protective layer, it is possible to prevent the second inorganic insulating layer 133 from breaking above the organic insulating layer 132 which is easily broken due to foreign matter.

In addition, by using a flexible material as the first substrate 101, the second substrate 112, and the counter substrate 102, a display device which can be bent can be obtained. In this case, by sandwiching the organic insulating layer 132 between the first inorganic insulating layer 131 and the second inorganic insulating layer 133, stress caused by bending of the display device can be relieved. In this way, damage to the sealing film due to bending of the display device can be prevented, and moisture and oxygen can be prevented from entering. As a result, since moisture or oxygen can be prevented from entering the light emitting element 130 in the display region 103, reliability of the display device can be improved.

### Third Embodiment

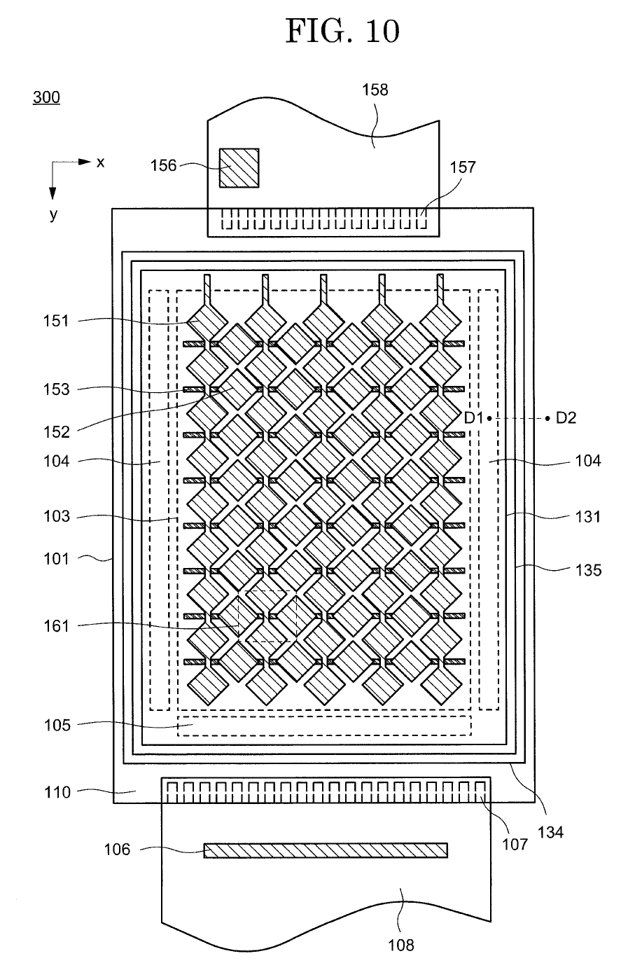

In the present embodiment, a display device having a structure partially different from the display device explained in the other embodiments is explained while referring to FIG. 10 to FIG. 14. In the present embodiment, a structure in which a touch sensor is arranged above the sealing film is explained in detail. Since the other structures are the same as the structures of the display device described in the other embodiments, a detailed explanation is omitted.

FIG. 10 is a schematic view showing a structure of a display device 300 according to one embodiment of the present invention, and shows a schematic structure in the case when the display device 300 is viewed in a planar view. In the display device 300 shown in FIG. 10, an on-cell type touch sensor 160 is arranged in the display region 103. The touch sensor 160 includes a first conductive layer 151, a second conductive layer 152 and wiring 153. In the first conductive layer 151, a plurality of diamond shaped pads are linearly connected in a y direction. The plurality of second conductive layers 152 are formed in a diamond shape and are connected linearly in a x direction by the wiring 153.

The first conductive layer 151 and the wiring 153 are drawn to the periphery region 110 on the outer side of the display region 103. The first conductive layer 151 and the wiring 153 are electrically connected to a touch panel FPC 158 via a terminal 157. In addition, a touch sensor driver IC 156 is externally arranged on the touch sensor FPC 158. A structure is possible in which the touch sensor driver IC 156 is arranged above a flexible printed substrate 108 without arranging the touch panel FPC 158 and terminal 157 so that the first conductive layer 151 and the wiring 153 are connected to the touch sensor driver IC 156 via the terminal 107.

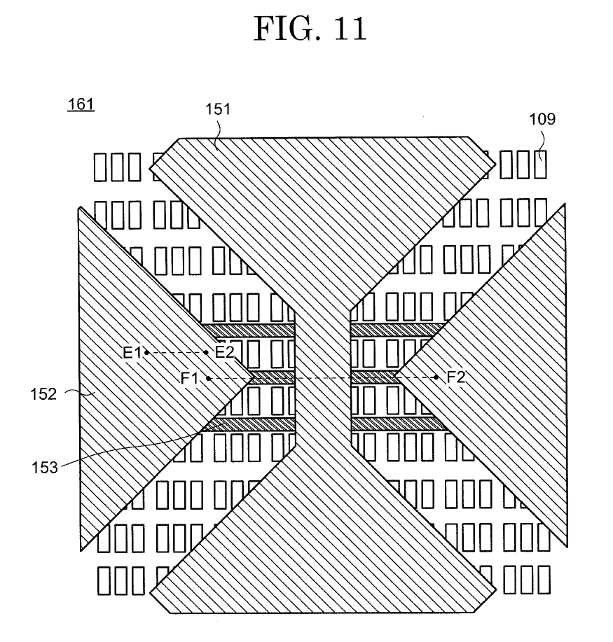

FIG. 11 is a diagram showing a planar view of an enlarged part of the display region 103. In FIG. 11, a plurality of pixels 109 are arranged in a matrix, and the first conductive layer 151 and a second conductive layer 152 are arranged so as to overlap the plurality of pixels 109. The first conductive layer 151 and the second conductive layer 152 are formed using a transparent conductive film. For example, an indium oxide based transparent conductive film (for example, ITO) or a zinc oxide based transparent conductive film (for example, IZO, ZnO) can be used as the transparent conductive film. In addition, the wiring 153 is formed in a single layer or a stacked layer using a metal material such as copper, titanium, molybdenum, or aluminum. The wiring 153 is arranged between two pixels 109 so light emitted from the pixel 109 is not blocked. In FIG. 11, although a structure is shown in which three wirings 153 are arranged connecting a plurality of second conductive layers 152, the number of wirings 153 is not particularly limited.

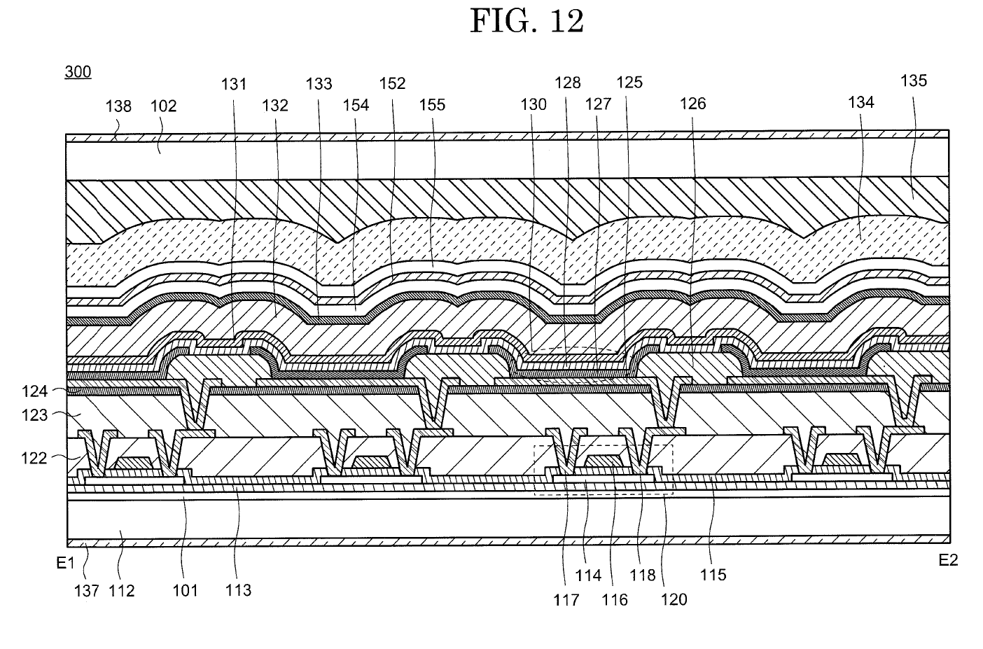

A cross-sectional view along line E1-E2 in FIG. 11 is shown in FIG. 12. FIG. 12 shows a diagram in which a second conductive layer 152 is formed above a plurality of light emitting elements 130. The first inorganic insulating layer 131, organic insulating layer 132 and second inorganic insulating layer 133 are arranged as a sealing film over the plurality of light emitting elements 130. A second insulating layer 154 is arranged above the second inorganic insulating layer 133, and a second conductive layer 152 is arranged above the second insulating layer 154. In addition, a third insulating layer 155 is arranged above the second conductive layer 152, and a sealing film protective layer 134 is arranged above the third insulating layer 155. Furthermore, the organic insulating layer 132 may have a shape so that unevenness of an underlying layer is planarized. In this case, each layer above the organic insulating layer 132 is arranged flat.

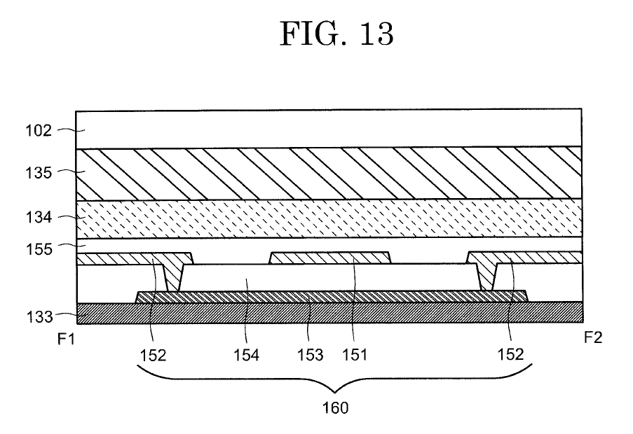

A cross-sectional view taken along the line F1-F2 in FIG. 11 is shown in FIG. 13. Furthermore, in FIG. 13, a layer formed under the second inorganic insulating layer 133 is omitted. As shown in FIG. 13, a touch sensor 160 is arranged above the second inorganic insulating layer 133. The touch sensor 160 includes a wiring 153, a first conductive layer 151, a second conductive layer 152 and a second insulating layer 154.

A manufacturing method of the display device 300 in the present embodiment is explained while referring to FIG. 13. The steps up to the step of forming the first inorganic insulating layer 131, the organic insulating layer 132, and the second inorganic insulating layer 133 which function as a sealing film on the first substrate 101 are similar to the manufacturing method in the other embodiments.

First, a wiring 153 is formed above the second inorganic insulating layer 133. A single layer or a stacked layer is formed using a metal material such as copper, titanium, molybdenum, or aluminum as the wiring 153. For example, a stacked structure of molybdenum and tungsten, a stacked structure of molybdenum and aluminum and molybdenum, and a stacked structure of titanium, aluminum, and titanium can be formed as the wiring 153.

Next, the second insulating layer 154 is formed above the wiring 153. The second insulating layer 154 is formed using a resist material or an organic resin. The resist material and the organic resin are applied by a printing method or an inkjet method and then cured. Following this, a contact hole which exposes the surface of the wiring 153 is formed in the second insulating layer 154.

Next, a transparent conductive film is formed above the second insulating layer 154, and processing is performed by a photolithography process to form the first conductive layer 151 and the second conductive layer 152. At this time, the second conductive layer 152 is connected via the contact hole of the wiring 153 and the second insulating layer 154. In this way, the plurality of second conductive layers 152 can be connected linearly in the x direction by the wiring 153. In addition, the first conductive layer 151 is formed so that a plurality of diamond shaped pads are linearly connected in the y direction.

An indium oxide based transparent conductive film (for example, ITO) or a zinc oxide based transparent conductive film (for example, IZO, ZnO) can be used as the transparent conductive film. Here, the film formation temperature of the transparent conductive film is preferred to be less than 100° C. When the film formation temperature of the transparent conductive film formed above a light emitting element 130 is increased, a light emitting layer included in the light emitting element 130 may deteriorate. As a result, in the case of forming a transparent conductive film after forming the light emitting element 130, it is preferred to form the film at the temperature described above. This makes it possible to suppress deterioration of the light emitting element 130 due to heat.

Next, a third insulating layer 155 is formed above the first conductive layer 151 and the second conductive layer 152. The third insulating layer 155 is formed using a resist material or an organic resin. The resist material and the organic resin are applied by a printing method or an inkjet method and then cured.

Next, a sealing film protective layer 134 is formed above the third insulating layer 155. The method of forming the sealing film protective layer 134 is the same as in the other embodiments. Furthermore, the sealing film protection layer 134 may be formed above the first conductive layer 151 and the second conductive layer 152 without forming the third insulating layer 155. Next, the counter substrate 102 and the first substrate 101 are bonded together with the adhesive material 135. The adhesive material 135 may contain a moisture absorbing substance such as calcium and zeolite.

By the steps described above, the display device 300 having the touch sensor 160 shown in FIG. 10 can be manufactured.

As shown in the present embodiment, in the display device according to the present invention, an on-cell type touch sensor can be arranged in the display region 103. By arranging the touch sensor under the sealing film protection layer, it is possible to prevent the touch sensor from breaking when bonding the array substrate and the counter substrate.

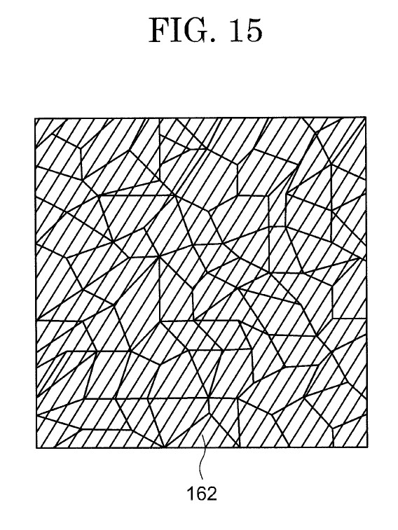

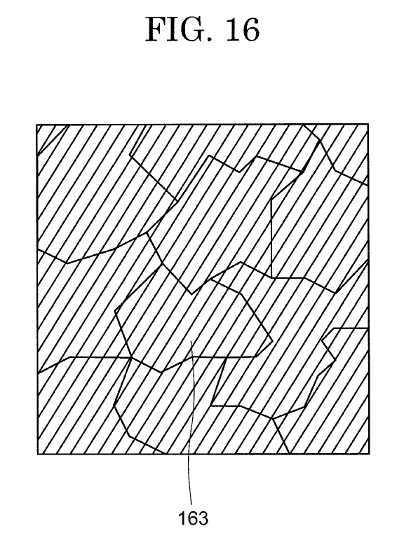

Here, the results of comparing the crystal particle diameter of a transparent conductive film used as the conductive layer of a touch panel with the crystal particle diameter of a transparent conductive film used as an anode of a light emitting element are explained. FIG. 15 is a schematic view of the crystal grain diameter of the transparent conductive film used as the conductive layer of a touch panel. In addition, FIG. 16 is a schematic view of the crystal grain diameter of the transparent conductive film used as an anode of a light emitting element.

As described in the present embodiment, the transparent conductive film used as the conductive layer of a touch panel is formed above a light emitting layer of a light emitting element. In order to prevent the light emitting layer from deteriorating due to heat, it is preferred that the film forming temperature of the transparent conductive film used as the conductive layer of the touch panel is less than 100° C. However, when the film forming temperature is less than 100° C., crystallization of the transparent conductive film does not proceed, and thereby the crystal grain diameter of the average transparent conductive film becomes small as shown in FIG. 15. On the other hand, the transparent conductive film used as the anode of the light emitting element is formed before the light emitting layer is formed. Therefore, since film deposition can be performed at a relatively high temperature (for example, 230° C.), crystallization of the transparent conductive film progresses and the crystal grain diameter of the average transparent conductive film can be increased as shown in FIG. 16.

As explained above, the crystal grain diameter of the transparent conductive film used as the conductive layer of the touch panel is smaller than the crystal grain diameter of the transparent conductive film used as the anode of the light emitting element.

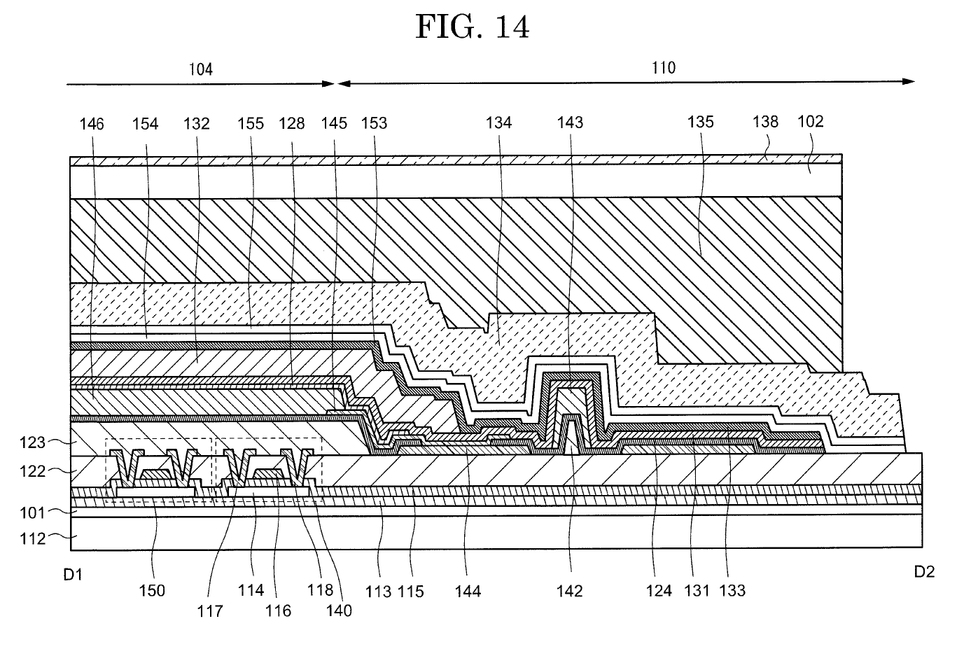

FIG. 14 shows a cross-sectional view taken along line D1-D2 in FIG. 10. The cross-sectional view shown in FIG. 14 is a cross-sectional view of the scanning line driving circuit 104 and the periphery region 110. As shown in FIG. 14, a wiring 153 is arranged above the second inorganic insulating layer 133. The wiring 153 is routed in the periphery region 110 and connected to the terminal 157 shown in FIG. 10. The wiring 153 is arranged in contact with the end part of the protective film 124, the end part of the first inorganic insulating layer 131, and the end part of the second inorganic insulating layer 133. In addition, a second insulating layer 154 is arranged above the wiring 153.

In addition, the same as in the other embodiments, in the periphery region 110, the first inorganic insulating layer 131 includes a region in contact with the second inorganic insulating layer 133. In this way, adhesion between the first inorganic insulating layer 131 and the second inorganic insulating layer 133 can be improved. In addition, the first inorganic insulating layer 131 includes a region in contact with the protective film 124. Since the first inorganic insulating layer 131 and the protective film 124 are each formed from an inorganic insulating material, it is possible to improve adhesion. In this way, it is possible to prevent moisture and oxygen from entering from the periphery region 110. In addition, by arranging the first convex part and the second convex part in the periphery region 110, it is possible to increase the region where the first inorganic insulating layer 131 and the second inorganic insulating layer 133 are in contact with each other. In this way, it possible to prevent peeling of the first inorganic insulating layer 131 and the second inorganic insulating layer 133.

In addition, by using a flexible material as the first substrate 101, the second substrate 112, and the counter substrate 102, a display device which can bend can be obtained. In this case, by sandwiching the organic insulating layer 132 between the first inorganic insulating layer 131 and the second inorganic insulating layer 133, stress caused by bending of the display device can be relieved. In this way, damage to the sealing film due bending of the display device can be prevented, and the entrance of moisture and oxygen can be prevented. As a result, since it is possible to prevent moisture or oxygen from entering the light emitting element 130 in the display region 103, reliability of the display device can be improved.

A person skilled in the art could appropriately add, delete or change design elements on the basis of the display device explained as embodiments and examples of the present invention, or those in which addition, omission, or changes in conditions of the processes are also included in the scope of the present invention as long as they do not depart from the concept of the present invention. In addition, each of the embodiments described above can be combined with each other within a range where no technical contradiction occurs.

In addition, even if other actions and effects different from the actions and effects brought about by modes of the embodiments described above are obvious from the description of the present specification or those which can be easily predicted by a person skilled in the art, they are naturally to be interpreted as belonging to the present invention.

What is claimed is:

1. A display device comprising:
a first substrate;
a second substrate opposed to the first substrate;
a display region between the first substrate and the second substrate;
a peripheral region outside the display region between the first substrate and the second substrate;
an adhesive member adhering the first substrate and the second substrate;
an interlayer insulating film between the first substrate and the second substrate;
a light emitting element arranged in the display region;
a sealing film between the interlayer insulating film and the second substrate, the light emitting element and the interlayer insulating film arranged between the sealing film and the first substrate; and
a sealing film protective layer between the sealing film and the second substrate, the adhesive member arranged between the sealing film protective layer and the second substrate,
wherein
the sealing film includes a first inorganic insulating film, an organic insulating film, and a second inorganic insulating film,
the sealing film protective layer has a region in contact with an end part of the first inorganic insulating film and an end part of the second inorganic insulating film in the peripheral region,
the first inorganic insulating film has a region in contact with the second inorganic insulating film in the peripheral region, and
the adhesive member does not overlap an end part of the sealing film protective layer in the peripheral region.

2. The display device according to claim 1, further comprising:
a planarizing film over the first substrate; and
a protective film over the planarizing film,
wherein
the first inorganic insulating film contacts with the protective film in the periphery region.

3. The display device according to claim 1, further comprising:
a planarizing film over the interlayer insulating film;
a protective film over the planarizing film; and
a first convex part and a second convex part arranged in the peripheral region,
wherein
the first convex part is arranged over the interlayer insulating film, and the second convex part is arranged over the protective film, and
the first convex part and the second convex part overlap via the protective film.

4. The display device according to claim 1, wherein the adhesive member includes a moisture adsorbing substance.

5. The display device according to claim 1, wherein the first substrate and the second substrate have flexibility.

6. A display device comprising:
a first substrate;
a second substrate arranged with a barrier layer on a surface opposing the first substrate;
a display region between the first substrate and the second substrate;
a peripheral region outside the display region between the first substrate and the second substrate;
an adhesive member adheres the first substrate and the second substrate;
an interlayer insulating film between the first substrate and the second substrate;
a light emitting element arranged in the display region;
a sealing film between the interlayer insulating film and the second substrate, the light emitting element and the interlayer insulating film arranged between the sealing film and the first substrate; and
a sealing film protective layer between the sealing film and the second substrate, the adhesive member arranged between the sealing film protective layer and the second substrate,
wherein
the second substrate includes a barrier film opposite the first substrate,
the sealing film includes a first inorganic insulating film, an organic insulating film, and a second inorganic insulating film,
the first inorganic insulating film has a region in contact with the second inorganic insulating film in the peripheral region,
an end part of the sealing film protective layer is arranged directly above the second inorganic insulating film in the peripheral region, and
the adhesive member contacts with the end part of the sealing film protective layer, an end part of the first inorganic insulating film and an end part of the second inorganic insulating film in the peripheral region.

7. The display device according to claim 6, further comprising:
a planarizing film over the first substrate; and
a protective film over the planarizing film,
wherein
the first inorganic insulating film contacts with the protective film in the periphery region.

8. The display device according to claim 6, further comprising:
a planarizing film over the interlayer insulating film;
a protective film over the planarizing film; and
a first convex part and a second convex part arranged in the peripheral region,
wherein
the first convex part is arranged over the interlayer insulating film, and the second convex part is arranged over the protective film, and
the first convex part and the second convex part overlap via the protective film.

9. The display device according to claim 6, wherein the adhesive member includes a moisture adsorbing substance.

10. The display device according to claim 6, wherein the adhesive member has higher moisture resistance than the sealing film.

11. The display device according to claim 6, wherein. the first substrate and the second substrate have flexibility.

12. A display device comprising:
a first substrate;
a second substrate opposed to the first substrate;
a display region between the first substrate and the second substrate;
a touch sensor between the display region and the second substrate;
a peripheral region outside the display region between the first substrate and the second substrate;
an adhesive member arranged in the peripheral region adhering the first substrate and the second substrate;
an interlayer insulating film between the first substrate and the second substrate;
a light emitting element arranged in the display region;
a sealing film between the interlayer insulating film and the second substrate, the light emitting element and the interlayer insulating film arranged between the sealing film and the first substrate; and
a sealing film protective layer between the sealing film and the second substrate, the adhesive member arranged between the sealing film protective layer and the second substrate,
wherein
the touch sensor is arranged between the sealing film protective layer and the sealing film,
the touch sensor includes a first electrode, an insulating film, and a second electrode,
the sealing film includes a first inorganic insulating film, an organic insulating film, and a second inorganic insulating film,
the sealing film protective layer has a region in contact with an end part of the second inorganic insulating film in the peripheral region,
the first inorganic insulating film has a region in contact with the second inorganic insulating film in the peripheral region, and
the adhesive member does not overlap an end part of the sealing film protective layer in the peripheral region.

13. The display device according to claim 12, further comprising:
a planarizing film over the first substrate; and
a protective film over the planarizing film,
wherein
the first inorganic insulating film contacts with the protective film in the periphery region.

14. The display device according to claim 12, further comprising:
a planarizing film over the interlayer insulating film;
a protective film over the planarizing film; and
a first convex part and a second convex part arranged in the peripheral region,
wherein
the first convex part is arranged over the interlayer insulating film, and the second convex part is arranged over the protective film, and
the first convex part and the second convex part overlap via the protective film.

15. The display device according to claim 12, wherein the adhesive member includes a moisture adsorbing substance.

16. The display device according to claim 12, wherein the first substrate and the second substrate have flexibility.
